(19) United States
(12) Patent Application Publication
(10) Pub. No.: US 2018/0018493 A1
(43) Pub. Date: Jan. 18, 2018

(54) FINGERPRINT IDENTIFICATION DEVICE AND MANUFACTURING METHOD THEREOF

(71) Applicant: KEYCORE TECHNOLOGY CORP., Zhuhei City (TW)

(72) Inventors: Wei-Cheng Lin, Zhudong Township (TW); Chien-Jen Hsiao, Zhudong Township (TW); Shih-Hsiu Tseng, Zhudong Township (TW)

(21) Appl. No.: 15/210,857

(22) Filed: Jul. 14, 2016

(51) Int. Cl. G06K 9/00; H05K 3/30; H05K 3/06

(52) U.S. Cl. CPC G06K 9/0002; H05K 3/06; H05K 3/30

(57) ABSTRACT

A fingerprint identification device and a manufacturing method of the fingerprint identification device. The fingerprint identification device includes a substrate, a sensation electrode layer and a fingerprint identification sensation chip. The substrate has a first face, a second face and multiple perforations in connection with the first and second faces. The sensation electrode layer is disposed on the first face of the substrate and has multiple first electrodes, multiple second electrodes and an insulation layer. The first and second electrodes and the insulation layer are laminated with each other. A part of the insulation layer is disposed between the first and second electrodes and another part of the insulation layer encloses the first and second electrodes. The fingerprint identification sensation chip is disposed on the second face of the substrate.

### BACKGROUND OF THE INVENTION

### 1. Field of the Invention

The present invention relates generally to a fingerprint identification device and a manufacturing method thereof, and more particularly to a fingerprint identification device and a manufacturing method thereof, which can improve the shortcoming of complicated structure of the conventional fingerprint identification device.

### 2. Description of the Related Art

The current fingerprint identification function is a basic security system applied to a mobile device. The conventional fingerprint identification devices can be classified into two major types, that is, independent type or integrated type. The independent type can be further classified into contact type and non-contact type. With respect to the contact type, the fingerprint in contact with the fingerprint identification device is directly identified by means of the sensation electrodes. Such fingerprint identification device is generally disposed on a contact section or independently disposed on a non-contact section. With respect to the non-contact type, the fingerprint is identified by the fingerprint identification device via ultrasonic wave. The location of the non-contact type fingerprint identification device is not limited to the contact section or the non-contact section.

The fingerprint identification technique has been developed for years and is mature now. However, as a whole, the structural design of the fingerprint identification device still needs to be improved and novelized. Moreover, there is a trend to manufacture lighter and thinner mobile device. Therefore, it has become a critical issue how to design a fingerprint identification device applicable to a narrow space.

Also, at the present stage, it is a most important issue how to simplify the manufacturing process and the structure of the fingerprint identification device so as to facilitate the use of the fingerprint identification device and enhance the fingerprint identification ratio.

### SUMMARY OF THE INVENTION

It is therefore a primary object of the present invention to provide a fingerprint identification device, which has simplified structure.

It is a further object of the present invention to provide a simplified manufacturing method of a fingerprint identification device.

To achieve the above and other objects, the fingerprint identification device of the present invention includes a substrate, a sensation electrode layer, a fingerprint identification sensation chip and multiple conductive layers.

The substrate has a first face, a second face and multiple perforations in connection with the first and second faces. The sensation electrode layer is disposed on the first face of the substrate. The sensation electrode layer has multiple first electrodes, multiple second electrodes and an insulation layer. The first and second electrodes and the insulation layer are laminated with each other. A part of the insulation layer is disposed between the first and second electrodes and another part of the insulation layer encloses the first and second electrodes. The fingerprint identification sensation chip is disposed on the second face of the substrate. The conductive layers are partially positioned in the perforations of the substrate to extend through the perforations and partially disposed on the second face of the substrate. The first and second electrodes are electrically connected to the fingerprint identification sensation chip via the conductors.

To achieve the above and other objects, the manufacturing method of the fingerprint identification device of the present invention includes steps of:

providing a substrate and coating a first metal coating on one face of the substrate;

etching the first metal coating by means of photolithography to form multiple first electrodes;

coating an insulation layer on the first electrodes and a surface of the substrate;

coating a second metal coating on one face of the insulation layer;

etching the second metal coating by means of photolithography to form multiple second electrodes;

perforating the substrate from the other face to the face with the multiple first electrodes to form multiple perforations;

coating a third metal coating on the face of the substrate with the multiple perforations and at the same time filling the third metal coating into the perforations;

etching the third metal coating by means of photolithography to form a conductive layer with multiple conductors; and

disposing a fingerprint identification sensation chip onto the conductive layer to connect with the substrate and electrically connect with the conductive layer.

By means of the fingerprint identification device of the present invention and the manufacturing method of the fingerprint identification device of the present invention, the shortcoming of too complicated structure of the conventional fingerprint identification device is eliminated.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view of a first embodiment of the fingerprint identification device of the present invention;

FIG. 2 is a sectional assembled view of the first embodiment of the fingerprint identification device of the present invention;

FIG. 3 is a sectional assembled view of a second embodiment of the fingerprint identification device of the present invention;

FIG. 4 is a flow chart of the manufacturing method of the fingerprint identification device of the present invention;

FIG. 5 is a view showing a step of the manufacturing method of the fingerprint identification device of the present invention;

FIG. 6 is a view showing another of the manufacturing method of the fingerprint identification device of the present invention;

FIG. 7 is a view showing still another step of the manufacturing method of the fingerprint identification device of the present invention; and

FIG. 8 is a view showing still another step of the manufacturing method of the fingerprint identification device of the present invention.

### DETAILED DESCRIPTION OF THE PREFERRED EMBODIMENTS

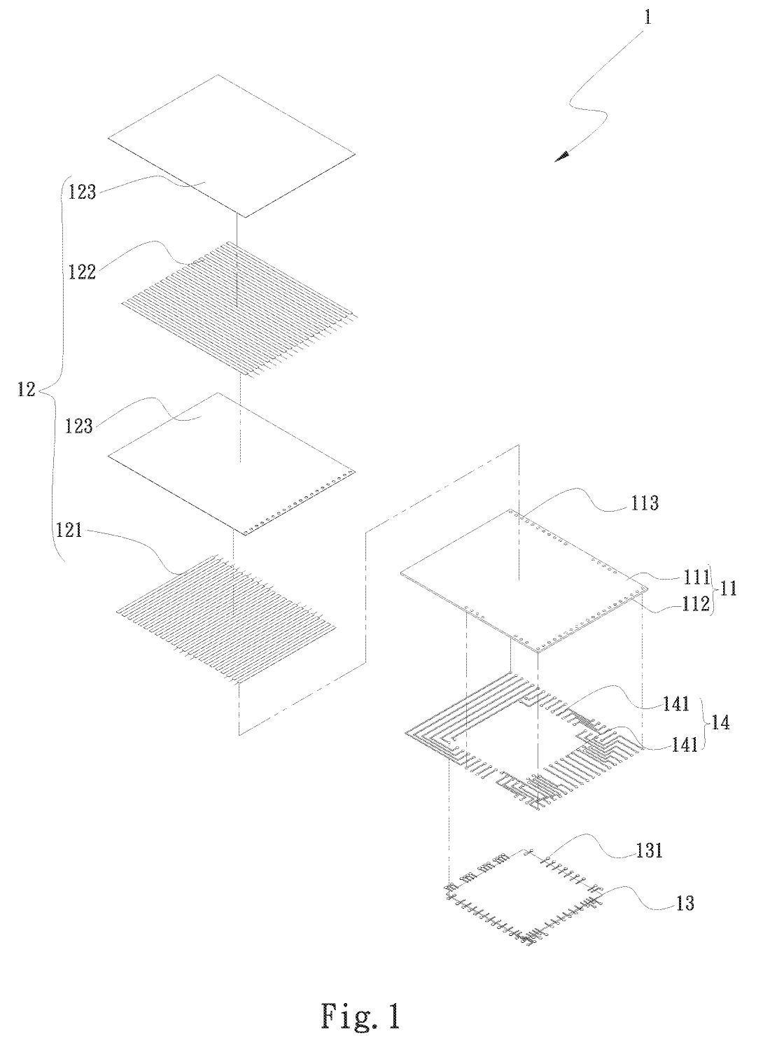

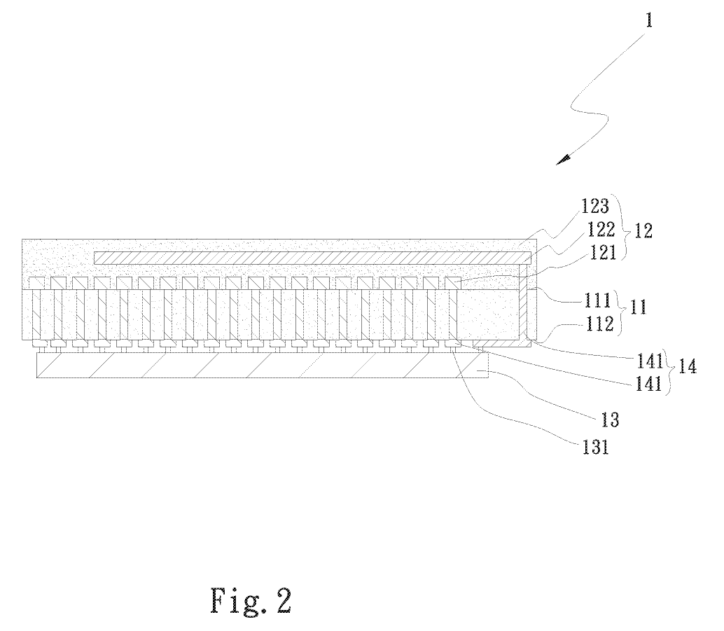

Please refer to FIGS. 1 and 2. FIG. 1 is a perspective exploded view of a first embodiment of the fingerprint identification device of the present invention. FIG. 2 is a sectional assembled view of the first embodiment of the fingerprint identification device of the present invention. The fingerprint identification device 1 includes a substrate 11, a sensation electrode layer 12, a fingerprint identification sensation chip 13 and a conductive layer 14.

The substrate 11 has a first face 111, a second face 112 and multiple perforations 113. The first and second faces 111, 112 are respectively positioned on the upper and lower faces of the substrate 11. The perforations 113 are formed through the substrate 11 between the first and second faces 111, 112 in connection therewith. The diameter of the perforations 113 ranges from 1 μm to 25 μm.

The sensation electrode layer 12 is disposed on the first face 111 of the substrate 1. The sensation electrode layer 12 has multiple first electrodes 121, multiple second electrodes 122 and an insulation layer 123. The first and second electrodes 121, 122 and the insulation layer 123 are laminated with each other. A part of the insulation layer 123 is disposed between the first and second electrodes 121, 122 and another part of the insulation layer 123 encloses the first and second electrodes 121, 122.

The first electrodes 121 are X-directional electrodes, while the second electrodes 122 are Y-directional electrodes. The first and second electrodes 121, 122 are insulated from each other by the insulation layer 123. The first and second electrodes 121, 122 are selectively electrically connected to the fingerprint identification sensation chip 13 via the conductive layer 14. The insulation layer 123 is SiO₂ or OverCoated.

The fingerprint identification sensation chip 13 is disposed on the second face 112 of the substrate 11. The fingerprint identification sensation chip 13 has multiple pins 131. The conductive layer 14 has multiple conductors 141. The conductors 141 are partially positioned in the perforations 113 of the substrate 11 to extend through the perforations 113 and partially disposed on the second face 112 of the substrate 11. The first and second electrodes 121, 122 are electrically connected to the pins 131 of the fingerprint identification sensation chip 13 via the conductors 141.

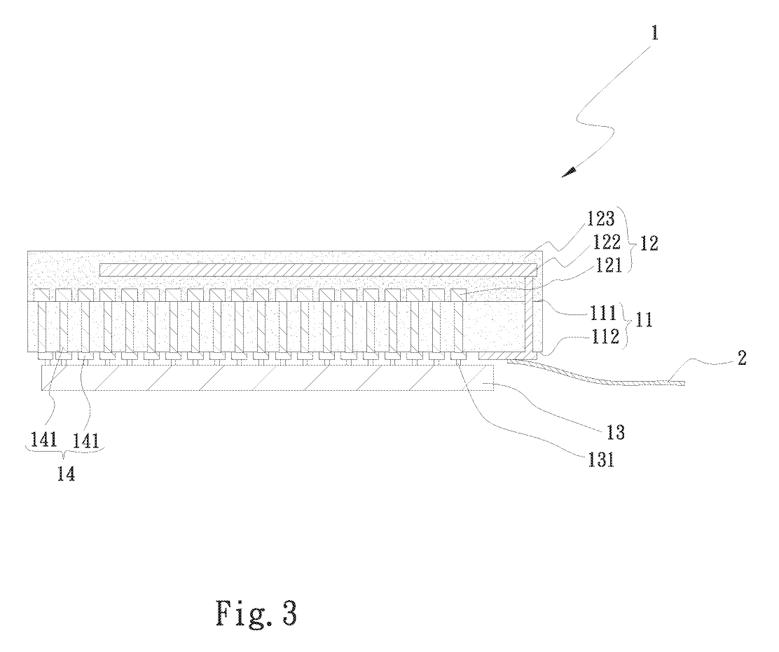

Please now refer to FIG. 3, which is a sectional assembled view of a second embodiment of the fingerprint identification device of the present invention. The second embodiment is partially identical to the first embodiment in structure and thus will not be repeatedly described hereinafter. The second embodiment is different from the first embodiment in that the second embodiment further has a flexible circuit board 2 electrically connected to the sensation electrode layer 12 or the fingerprint identification sensation chip 13.

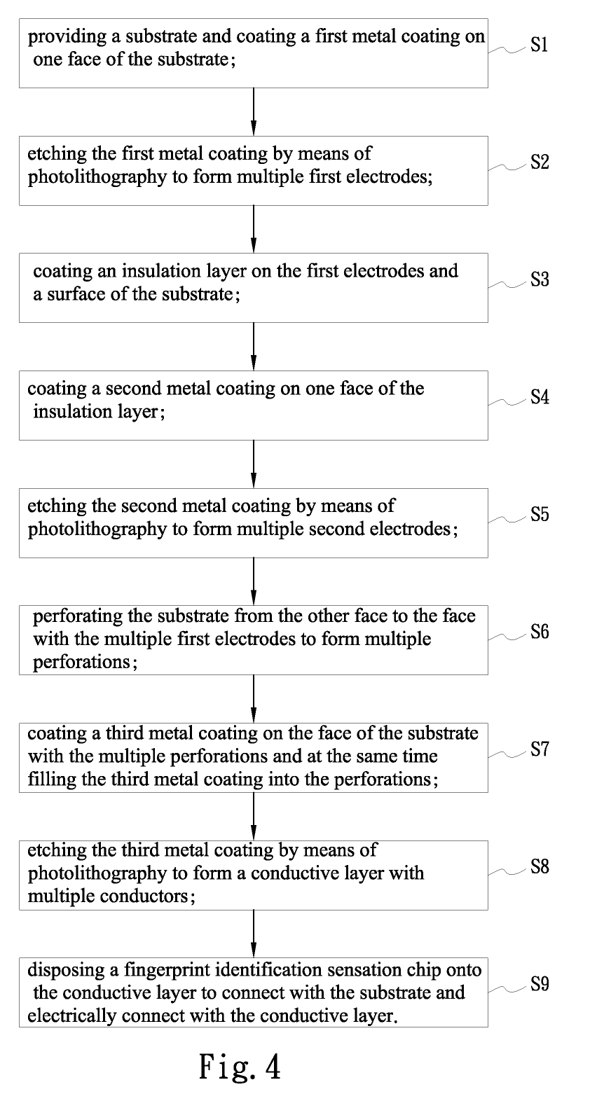

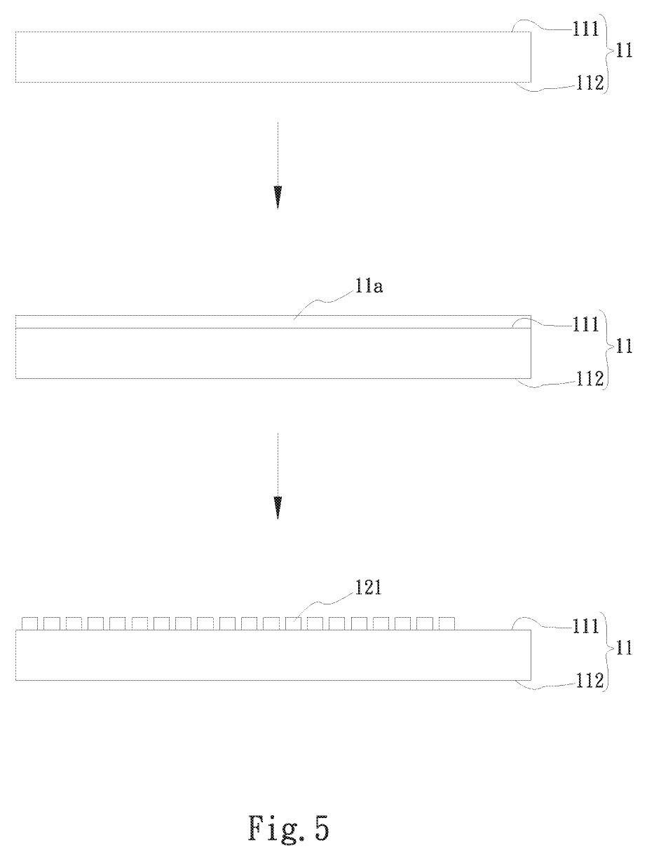

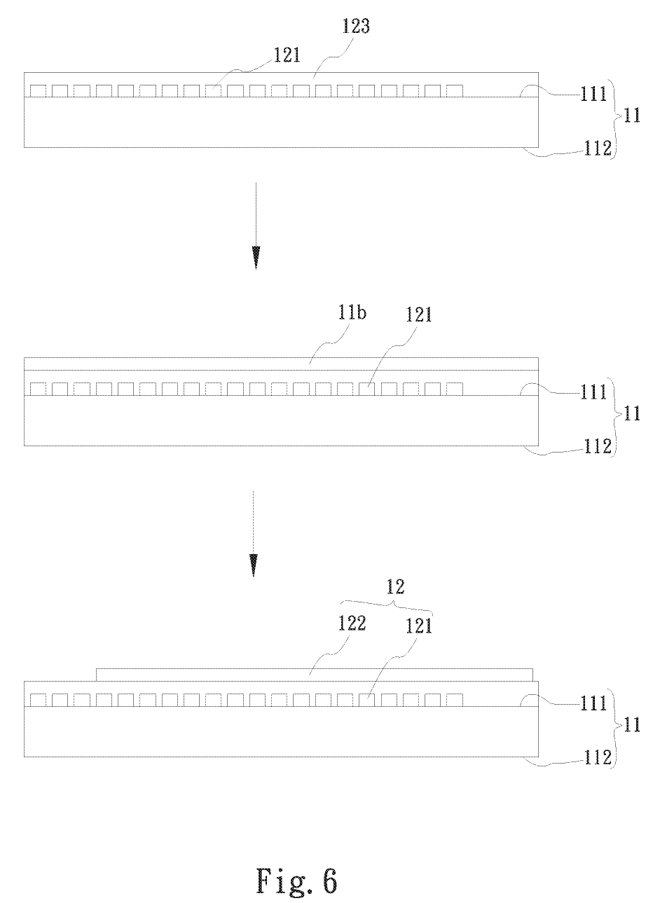

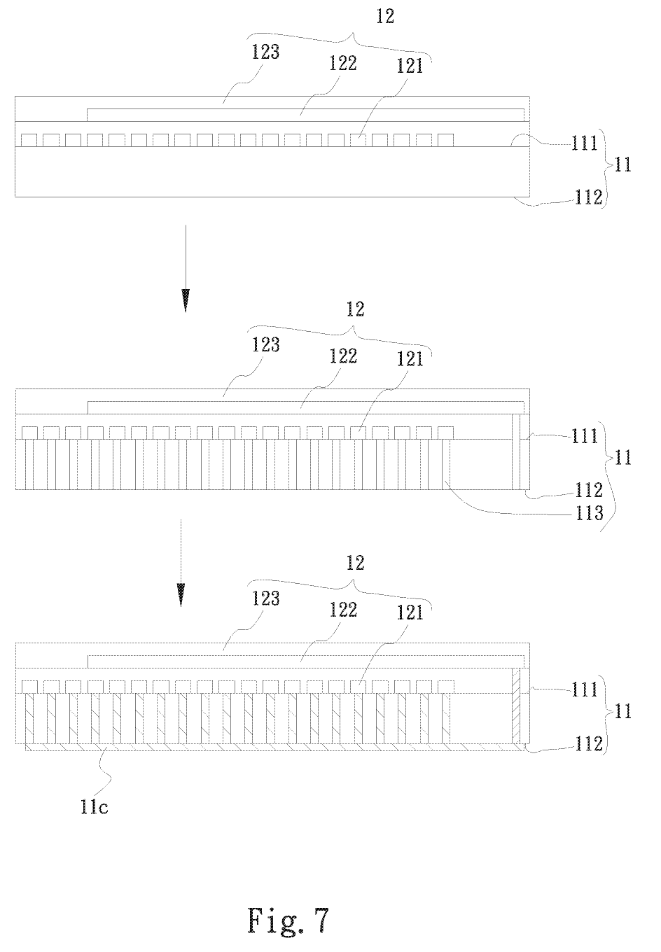

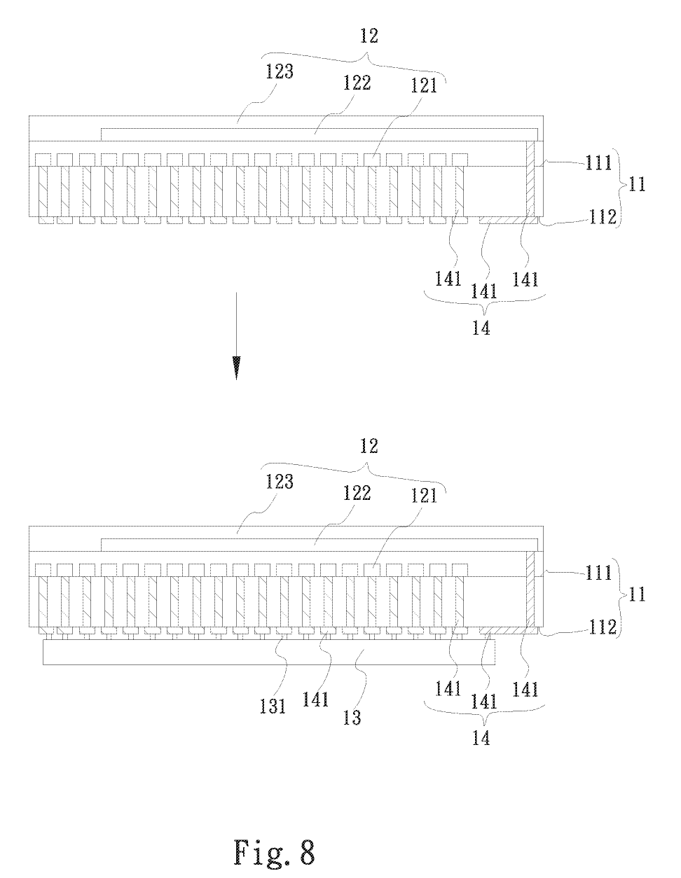

Please now refer to FIGS. 4, 5, 6, 7 and 8. FIG. 4 is a flow chart of the manufacturing method of the fingerprint identification device of the present invention. FIG. 5 is a view showing a step of the manufacturing method of the fingerprint identification device of the present invention. FIG. 6 is a view showing another of the manufacturing method of the fingerprint identification device of the present invention. FIG. 7 is a view showing still another step of the manufacturing method of the fingerprint identification device of the present invention. FIG. 8 is a view showing still another step of the manufacturing method of the fingerprint identification device of the present invention. Also referring to FIGS. 1 to 3, the manufacturing method of the fingerprint identification device of the present invention includes steps of:

S1. providing a substrate and coating a first metal coating on one face of the substrate, a substrate 11 being provided as a substrate material, the substrate 11 being made of silicon material or glass material, the substrate 11 having an upper face and a lower face (a first face 111 and a second face 112), a first metal coating 11a being selectively deposited on the upper face (the first face 111) by means of coating;

S2. etching the first metal coating by means of photolithography to form multiple first electrodes, the first metal coating being etched by means of photolithography to form multiple first electrodes 121;

S3. coating an insulation layer on the first electrodes and the surface of the substrate, an insulation layer 123 being coated on the first electrodes 121 and the section of the substrate 11 that is free from the first electrodes 121 for insulation;

S4. coating a second metal coating on one face of the insulation layer, a second metal coating 11b being deposited on one face of the insulation layer 123 by means of coating;

S5. etching the second metal coating by means of photolithography to form multiple second electrodes, the second metal coating 11b being etched by means of photolithography to form multiple second electrodes 122;

S6. perforating the substrate from the other face to the face with the multiple first electrodes to form multiple perforations, the substrate 11 being perforated from the surface of the second face 112 to the first face 111 to form multiple perforations 113 in communication with the first and second faces 111, 112 of the substrate, the perforations 113 being formed by means of etching, drilling or laser perforation;

S7. coating a third metal coating on the face of the substrate with the multiple perforations and at the same time filling the third metal coating into the perforations, a third metal layer 11c being coated on the second face 112 of the substrate 11 by means of coating, at the same time, the third metal coating 11c being filled into the perforations 113 previously formed on the substrate 11 to electrically connect with the first and second electrodes 121, 122;

S8. etching the third metal coating by means of photolithography to form a conductive layer with multiple conductors, the third metal coating 11c being etched by means of photolithography to form a conductive layer 14 with multiple conductors 141, the conductors 141 being such as the metal wiring and the wires disposed in the perforations 113; and

S9. disposing a fingerprint identification sensation chip onto the conductive layer to connect with the substrate and electrically connect with the conductive layer, a fingerprint identification sensation chip 13 being connected onto the conductive layer 14 of the substrate 11 by means of chip-on-glass (COG) process, the multiple pins 131 of the fingerprint identification sensation chip 13 being electrically connected to the conductive layer 14.

In the fingerprint identification device of the present invention and the manufacturing method of the fingerprint identification device of the present invention, the first and second electrodes 111, 112 are selectively transparent or nontransparent.

By means of the fingerprint identification device of the present invention and the manufacturing method of the fingerprint identification device of the present invention, the shortcomings of the conventional fingerprint identification device can be eliminated. Also, the precision of the fingerprint identification device can be greatly enhanced and the manufacturing cost of the fingerprint identification device can be greatly lowered.

The present invention has been described with the above embodiments thereof and it is understood that many changes and modifications in the above embodiments can be carried out without departing from the scope and the spirit of the invention that is intended to be limited only by the appended claims.

1. A fingerprint identification device comprising:
a substrate having a first face, a second face and multiple perforations in connection with the first and second faces, the substrate being made of glass material, the multiple perforations being formed by means of laser perforation;
a sensation electrode layer disposed on the first face of the substrate, the sensation electrode layer having multiple first electrodes, multiple second electrodes and an insulation layer, the first and second electrodes and the insulation layer being laminated with each other, a part of the insulation layer being disposed between the first and second electrodes and another part of the insulation layer enclosing the first and second electrodes;
a fingerprint identification sensation chip disposed on the second face of the substrate; and
a conductive layer having multiple conductors, the conductors being partially positioned in the perforations of the substrate to extend through the perforations and partially disposed on the second face of the substrate, the first and second electrodes being electrically connected to the fingerprint identification sensation chip via the conductors.

2. The fingerprint identification device as claimed in claim 1, further comprising a flexible circuit board electrically connected to the sensation electrode layer or the fingerprint identification sensation chip.

3. The fingerprint identification device as claimed in claim 1, wherein the first electrodes are X-directional electrodes, while the second electrodes are Y-directional electrodes, the first and second electrodes being insulated from each other by the insulation layer, the first and second electrodes being selectively electrically connected to the fingerprint identification sensation chip via the conductive layer.

4. The fingerprint identification device as claimed in claim 1, wherein the insulation layer is SiO2 or OverCoated.

5. The fingerprint identification device as claimed in claim 1, wherein the perforations have a diameter ranging from 1 μm to 25 μm.

6. A manufacturing method of a fingerprint identification device, comprising steps of:
providing a glass substrate and coating a first metal coating on one face of the glass substrate;
etching the first metal coating by means of photolithography to form multiple first electrodes;
coating an insulation layer on the first electrodes and a surface of the glass substrate;
coating a second metal coating on one face of the insulation layer;
etching the second metal coating by means of photolithography to form multiple second electrodes;
perforating the glass substrate from the other face to the face with the multiple first electrodes to form multiple perforations by means of laser perforation;
coating a third metal coating on the face of the glass substrate with the multiple perforations and at the same time filling the third metal coating into the perforations;
etching the third metal coating by means of photolithography to form a conductive layer with multiple conductors; and
disposing a fingerprint identification sensation chip onto the conductive layer to connect with the glass substrate and electrically connect with the conductive layer.

7. The manufacturing method of the fingerprint identification device as claimed in claim 6, wherein the first and second electrodes are selectively transparent or nontransparent.

8. (canceled)

9. The manufacturing method of the fingerprint identification device as claimed in claim 6, wherein the fingerprint identification sensation chip is connected onto the conductive layer of the substrate by means of chip-on-glass (COG) process.
